(19) United States
(12) Patent Application Publication
(10) Pub. No.: US 2015/0076978 A1
(43) Pub. Date: Mar. 19, 2015

(54) Self-Draining Gasket for an Enclosure

(71) Applicant: Jeffrey S. Ellingson, Woodbury, MN (US)

(72) Inventor: Jeffrey S. Ellingson, Woodbury, MN (US)

(21) Appl. No.: 14/488,224

(22) Filed: Sep. 16, 2014

Related U.S. Application Data
(60) Provisional application No. 61/878,051, filed on Sep. 16, 2013.

(51) Int. Cl. H05K 5/06; H05K 5/02

(52) U.S. Cl. CPC H05K 5/061; H05K 5/0217; H05K 5/0247; H05K 5/0226
USPC 312/229

(57) ABSTRACT

An enclosure having a housing with a front wall and a back wall, and an opening in the front wall. A door having a top and a bottom and an inner face and an outer face, and the door is rotatably attached to the housing. The door is configured to cover the opening when the door is in a closed position. A gasket is attached to the inner face of the door and located at least over a top of the opening of the housing when the door is in the closed position. The gasket is located closer to a top of the door in a center of the door, and the gasket is further from the top of the door as the gasket approaches opposing sides of the door.

### CROSS-REFERENCE TO RELATED APPLICATION

This patent application claims priority to provisional patent application entitled “Free Draining Door Gasket Top Seal For Electrical Enclosures” filed on Sep. 16, 2013, having Ser. No. 61/878,051, which is hereby incorporated by reference.

### BACKGROUND OF THE INVENTION

1. Field of the Invention

The present invention relates generally to sealing enclosures, and more particularly, to an apparatus for more effectively draining door seals on an enclosure.

2. Description of Related Art

Hygienic demands in the manufacturing practices of the food, dairy and pharmaceutical industries continue to increase. Part of these increasing demands includes improving the removal of collected water in the cleaning processes of electrical equipment enclosures used in these industries. One area of needed improvement involves designing electrical enclosures that do not allow puddles of water to collect on their components or structures. For example, the area between the access door and the access opening of an enclosure is an area where water can accumulate. If water does accumulate between the access door and the enclosure, water can also enter the enclosure when the door is opened which can result in damaged electrical equipment.

Accordingly, there is a need for a more effective design for eliminating water accumulation on and around a seal between the access door and the access opening of an enclosure.

### ASPECTS AND SUMMARY OF THE PRESENT INVENTION

One aspect of the present invention is to provide a self-draining gasket for a watertight enclosure.

Another aspect of the present invention is to provide a self-draining gasket that is attached to an access door of a watertight enclosure.

A further aspect of the present invention is to provide a self-draining gasket that is attached to an inner face of an access door of a watertight enclosure.

An additional aspect of the present invention is to strengthen a door of a watertight enclosure by providing additional support on the door to prevent the door from misshaping and thus breaching a watertight seal.

In order to achieve these aspects and others, the present invention provides a housing with a front wall and a back wall, and an access opening in the front wall. A door having a top and a bottom and an inner face and an outer face is rotatably attached to the housing. The door is configured to cover the opening when the door is in a closed position. A gasket is attached to the inner face of the door and located at least over a top of the opening of the housing when the door is in the closed position. The gasket is located closer to a top of the door in a center of the door, and the gasket is further from the top of the door as the gasket approaches opposing sides of the door.

In accordance with another embodiment of the present invention, an enclosure is provided having a housing with a front wall and a back wall, and an opening in the front wall. A door having a top and a bottom is rotatably attached to the housing, and the door is configured to cover the opening when the door is in a closed position. A gasket is attached to the front wall of the housing and is located at least over a top of the opening of the housing. The gasket is located closer to a top of the housing in a center of the housing, and the gasket is further from the top of the housing as the gasket approaches opposing sides of the front wall.

By pitching the gasket area on the top of the door or the front of the housing, water can be prevented from accumulating on the seal area. The apparatus of the present invention meets the requirements for UL50, UL 508A, and associations of: (1) Underwriters Laboratories, Inc. (UL); (2) Canadian Standards Association (CSA); and (3) Association of Standardization and Certification (ANCE). This invention can be used on all types of electrical UL50 and UL 508A enclosures, including: (1) enclosures for indoor locations, Types and/or NEMA rated: 1, 2, 5, 12 and 13; and (2) enclosures for indoor and outdoor locations, Types and/or NEMA rated: 3, 3R, 3S, 4, 4X, 6 and 6P.

The foregoing has outlined, rather broadly, the preferred features of the present invention so that those skilled in the art may better understand the detailed description of the invention that follows. Additional features of the invention will be described hereinafter that form the subject of the claims of the invention. Those skilled in the art should appreciate that they can readily use the disclosed invention and specific embodiments as a basis for designing or modifying other structures for carrying out the same purposes of the present invention, and that such other structures do not depart from the spirit and scope of the invention in its broadest form.

### BRIEF DESCRIPTION OF THE DRAWINGS

FIG. 1 is a perspective view of a watertight enclosure having a door in the open position and configured in accordance with a first embodiment of the present invention;

FIG. 1a is a view of the portion “1a” shown in FIG. 1;

FIG. 1b is a view of the portion “1b” shown in FIG. 1a;

FIG. 1c is a side view of the door shown in and taken along line 1c-1c of FIG. 1a;

FIG. 1d is an enlarged view of the circled portion “1d” shown in FIG. 1c;

FIG. 1e is a cross-sectional view shown in and taken along line 1e-1e of FIG. 1d looking downward on the door;

FIG. 1f is an enlarged view of the circled portion “1f” shown in FIG. 1e;

FIG. 2 is a rear view of an inner face of a door configured in accordance with a second embodiment of the present invention;

FIG. 2a is a view of the portion “2a” shown in FIG. 2;

FIG. 2b is a side view of the door shown in and taken along line 2b-2b of FIG. 2;

FIG. 2c is an enlarged view of the circled portion “2c” shown in FIG. 2b;

FIG. 3 is a rear view of an inner face of a door configured in accordance with a third embodiment of the present invention;

FIG. 3a is a view of the portion “3a” shown in FIG. 3;

FIG. 3b is a side view of the door shown in and taken along line 3b-3b of FIG. 3;

FIG. 3c is an enlarged view of the circled portion “3c” shown in FIG. 3b;

FIG. 4 is a rear view of an inner face of a door configured in accordance with a fourth embodiment of the present invention;

FIG. 4a is a view of the portion “4a” shown in FIG. 4;

FIG. 4b is a side view of the door shown in and taken along line 4b-4b of FIG. 4;

FIG. 4c is an enlarged view of the circled portion “4c” shown in FIG. 4b;

FIG. 5 is a perspective view of a watertight enclosure having a door in an open position and configured in accordance with a fifth embodiment of the present invention;

FIG. 5a is a view of the portion “5a” shown in FIG. 5;

FIG. 5b is a cross-sectional side view of the housing shown in FIG. 5; and

FIG. 5c is an enlarged cross-sectional view of the circled portion “5c” shown in FIG. 5b.

### DETAILED DESCRIPTION OF THE PREFERRED EMBODIMENTS

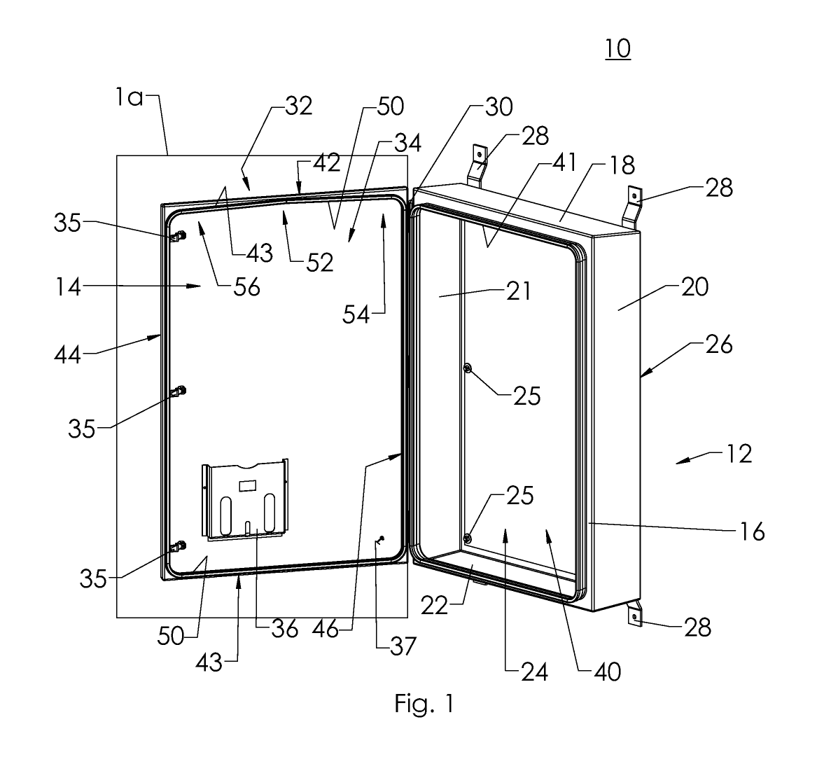

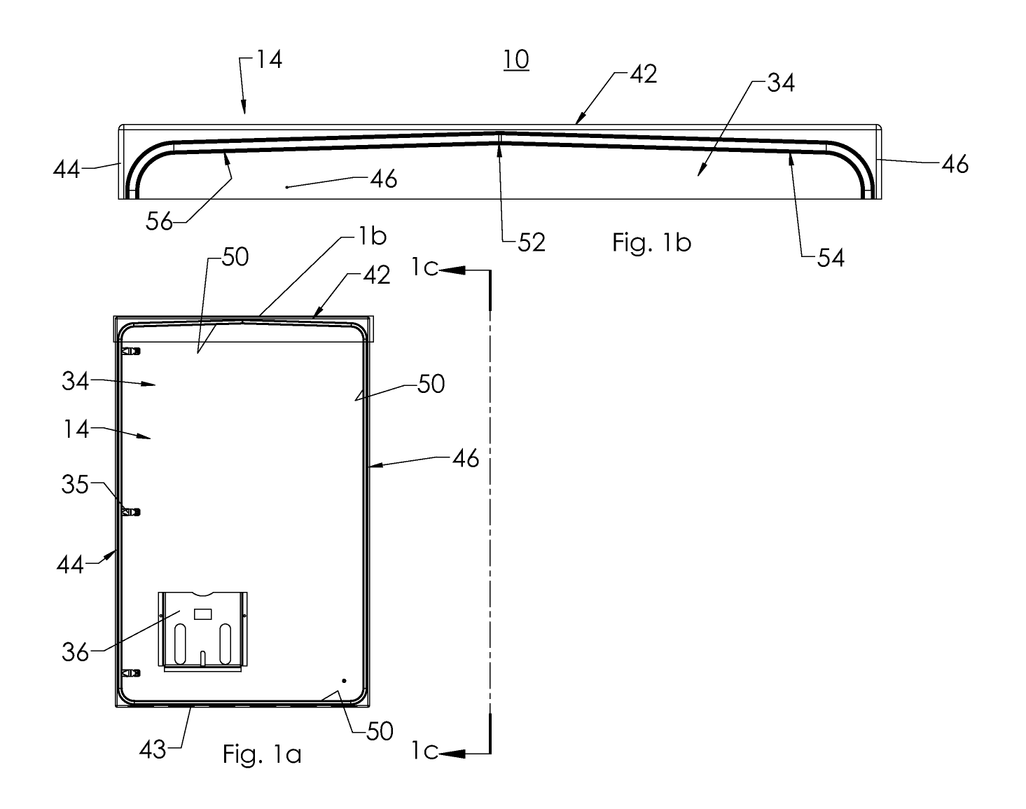

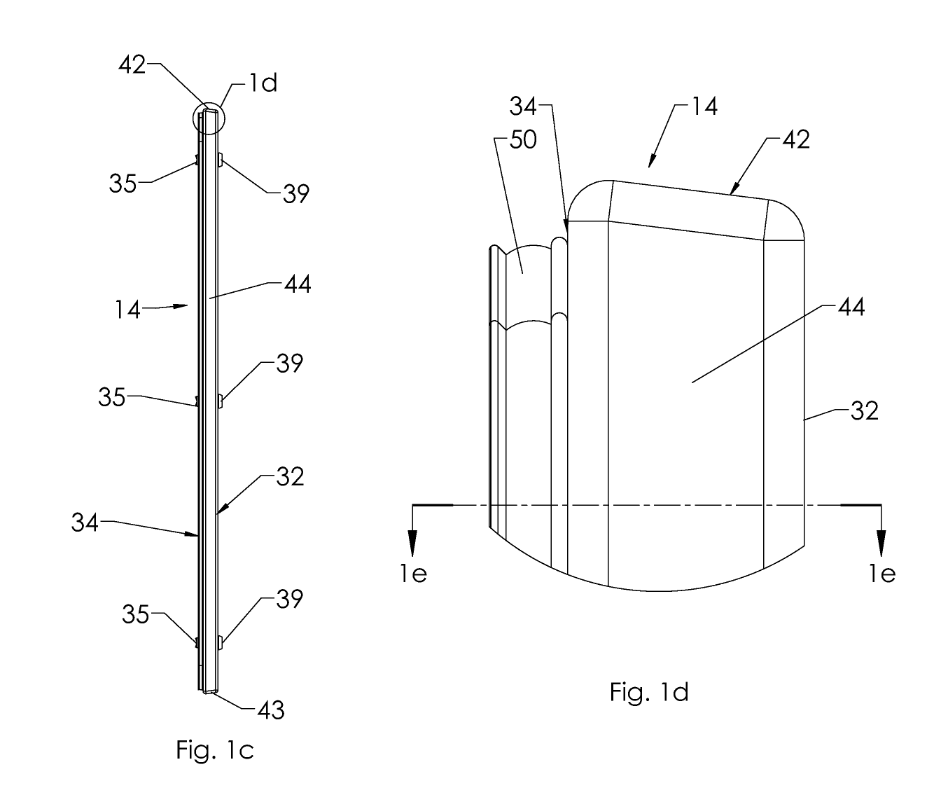

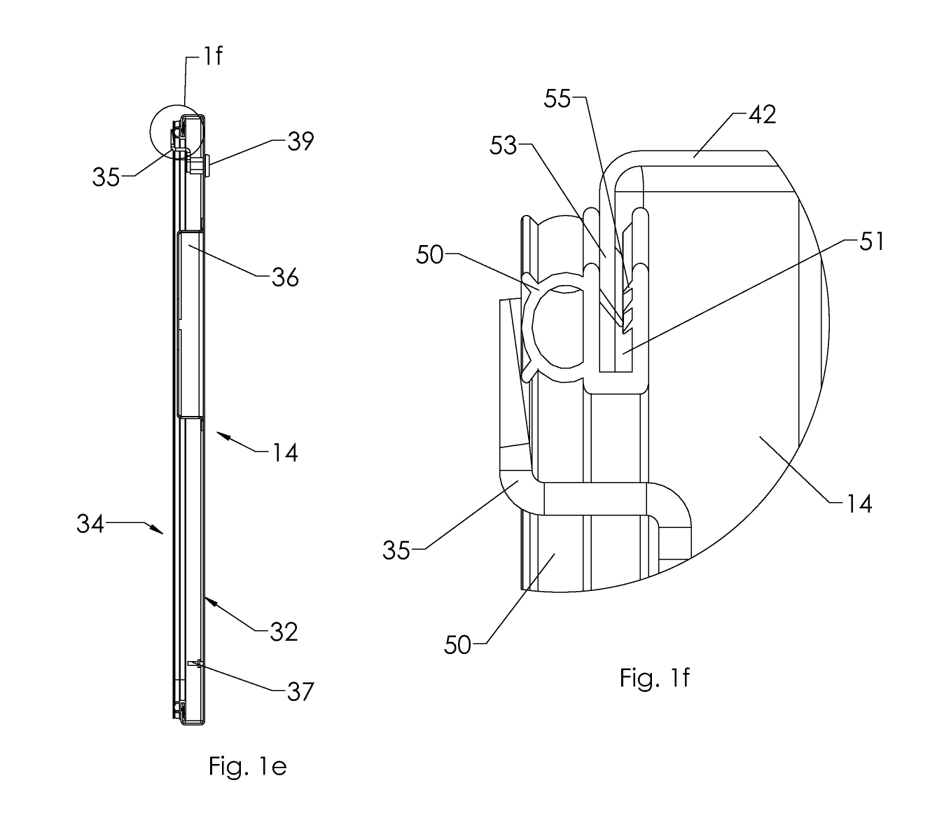

Referring now to the drawings, FIG. 1 is a perspective view of an enclosure 10, such as a watertight enclosure, configured in accordance with a preferred embodiment of the present invention. The enclosure 10 includes a housing 12 having a door 14 rotatably mounted to a front 16 of the housing 12. The housing 12 has a top wall 18, side walls 20, 21, and a bottom wall 22. A back panel 24 for mounting electronics is secured or mounted to a back wall 26 of the enclosure 10 using bolts 25. Brackets 28 on the back wall 26 of the housing 12 are used for securing the enclosure 10 to a vertical wall or other mounting surface.

The access door 14 is rotatably mounted to the front 16 of the housing 12 using a hinge 30 or other rotatable mounting fixture. The door 14 has an outer or front face 32 and an inner or rear face 34. Rotating levers or arms 35 on the inner face 34 of the door 14 function to lock the door 14 when the door 14 is in a closed the position. The levers 35 rotate to a position behind the front 16 to lock the door 14 in the closed position. A compartment 36 is located on the back face 34 of the door 14 for holding paper instructions. A grounding pin or post 37 is located on the inner face 34 of the door 14 for grounding electronics in the enclosure 10. An access opening 40 is located on the front 16 of the housing 12. The door 14 covers the opening 40 when the door 14 is in the closed position. The door 14 includes a top 42, a bottom 43, and sides 44 and 46.

In accordance with the present invention, a gasket 50 is connected to inner face 34 of the door 14 and located at least over a top 41 of the opening 40 of the housing 12 when the door 14 is in the closed position. The gasket 50 is located closer to a top 42 of the door 14 in a first location 52, and the gasket is located further from the top 42 of the door 14 in a second location 54 than the first location 52. The gasket 50 also is further from the top 42 of the door 14 in a third location 56. By angling the gasket 50 in a downward manner from a top 42 of the door 14, water contacting the top 43 of the gasket 50 will not pool or remain on the gasket 50, but will run off the gasket 50 to the sides 44 and 46 of the door 14 due to the force of gravity. By preventing water from accumulating or pooling on the gasket 50, the chance of water penetrating a seal between the inner face 34 of the door 14 and the front 16 of the housing 12 is greatly reduced. Furthermore, water is less likely to enter the housing 12 when the door 14 is opened.

FIG. 1a is a view of the portion “1a” shown in FIG. 1. Illustrated is the rear or inner face 34 of the door 14. The gasket 50 is shown adjacent to the periphery of the door 14, except for being curved in the corners and angled downward at the top 42 of the door 14. The rotating levers 35 and the compartment 36 also are illustrated.

FIG. 1b is an enlarged view of the portion “1b” shown in FIG. 1a showing the top 42 of the door 14. The gasket 50 is shown being angled downward toward the sides 44 and 46 of the door 14. The first location 52, the second location 54, and the third location 56 of the gasket 50 on the top 42 of the door 14 are illustrated.

FIG. 1c is a view of the side 46 of the door 14 shown in and taken along line 1c-1c of FIG. 1b. Shown are the rotating levers 35 of the inner face 34 of the door 14, and the knobs 39 on the outer face 34 of the door 14 for rotating and locking the door by rotating levers 35. The top 42 and the bottom 43 of the door 14 also are illustrated.

FIG. 1d is an enlarged view of the circled portion “1d” shown in FIG. 1c. FIG. 1d is an enlarged view showing the gasket 50 connected to the inner face 34 of the door 14. The top 42 of the door 14 is angled downward toward the outer face 32 of the door 14 to drain water away from the gasket 50.

FIG. 1e is a cross-sectional view shown in and taken along line 1e-1e of FIG. 1d. Shown is a cross-sectional view of the door 14 looking downward showing the rotating levers 35 of the inner face 34 of the door 14, and knobs 39 of the outer face 32 of the door 14 for turning the rotating levers 35. The compartment 36 is shown for holding informational papers, and the grounding post 37 also is illustrated.

FIG. 1f illustrates an enlarged view of the cross-section shown in circled portion “1f” of FIG. 1e. The gasket 50 is shown on a rim 53 connected to the top 42 on the inner face 34 of the door 14. The gasket 50 includes a slot 51 for receiving the rim 53 to attach the gasket 50 to the door 14. The slot 51 includes fingers 55 for preventing the gasket 50 from slipping off the rim 53. The gasket 150 can be easily replaced if damaged or worn by sliding the gasket 50 off the rim 53, and replaced with a new gasket 50 that is slid back onto the rim 53.

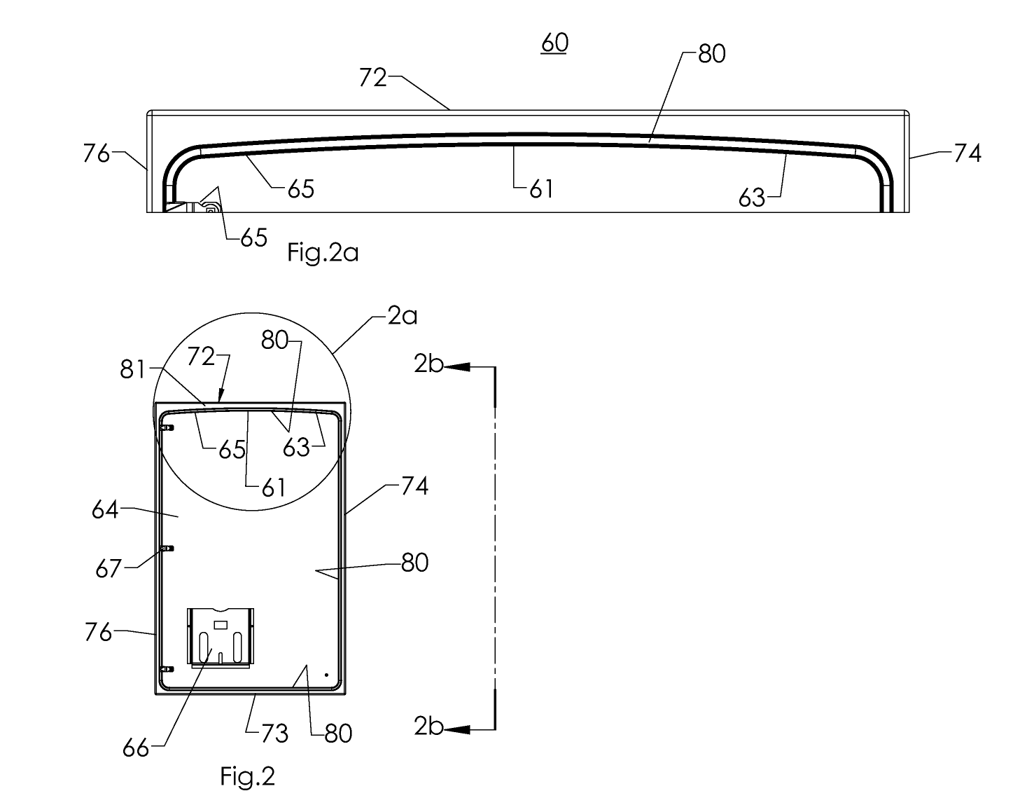

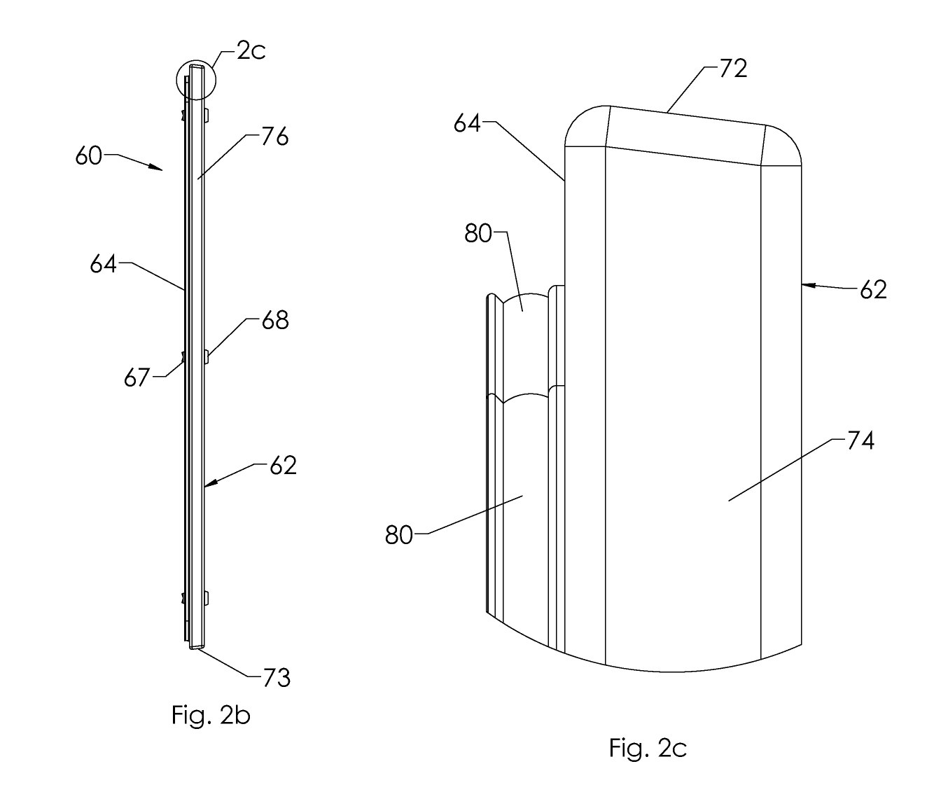

FIG. 2 illustrates an inner face 64 of a door 60 configured in accordance with a second embodiment of the present invention. The door 60, like door 14, is configured to seal an access opening of an enclosure in the closed position. The door 60 has an outer or front face and an inner or rear face 64. Rotating levers or arms 67 on the inner face 64 of the door 60 function to lock the door 60 when the door 60 is in a closed position. The levers 67 rotate to a position behind a front of an enclosure to lock the door 60 in the closed position. A compartment 66 is located on the inner, back, or rear face 64 of the door 60 for holding paper instructions. The door 60 includes a top 72, a bottom 73, and sides 74 and 76. A gasket 80 is shown adjacent to the periphery of the door 60, except for being curved in the corners and angled downward at the top 72 of the door 60.

In accordance with the present invention, a gasket 80 is connected to inner face 64 of the door 60 and located at least over a top of an opening of an enclosure when the door 60 is in the closed position. The gasket 80 is located closer to a top 72 of the door 80 in a first location 61, and the gasket is further from the top 72 of the door 60 in a second location 63 than the first location 61. The gasket 80 also is further from the top 72 of the door 60 in a third location 65. As a slight variation from the embodiment shown in FIG. 1, the top section 81 of the gasket 80 is rounded downward towards the sides 74 and 76 of the door 60.

By angling the gasket 80 in a downward manner from the top 81, water contacting on the top of 81 of gasket 80 will not pool or remain on the gasket 80, but will run off the gasket 80 to the sides 74 and 76 of the door 60 due to the force of gravity. By preventing water from accumulating or pooling on the gasket 80, the chance of water penetrating a seal between the inner face 64 of the door 60 and the front of an enclosure are greatly reduced. Furthermore, water is less likely to enter an access opening of an enclosure when the door 14 covering the access opening is opened.

FIG. 2a is an enlarged view of the portion “2b” shown in FIG. 2 showing the top 72 of the door 60. The gasket 80 is shown being angled downward towards the sides 74 and 76 of the door 60. The first location 61, the second location 63, and the third location 65 of the gasket 80 proximate the top 72 of the door 60 are illustrated.

FIG. 2b is a side view of the side 76 of the door 60 shown in and taken along line 2b-2b of FIG. 2a. Shown are the rotating levers 67 of the inner face 64 of the door 60, and the knobs 68 on the outer face 62 of the door 60 for rotating and locking the rotating levers 67. The top 72 and the bottom 73 of the door 60 also are illustrated.

FIG. 2c is an enlarged view of the circled portion 2c shown in FIG. 2b. FIG. 2c is an enlarged view showing the gasket 80 connected to the inner face 64 of the door 60. The top 72 of the door 60 is angled downward toward the outer face 62 of the door 60 to drain water away from the gasket 80.

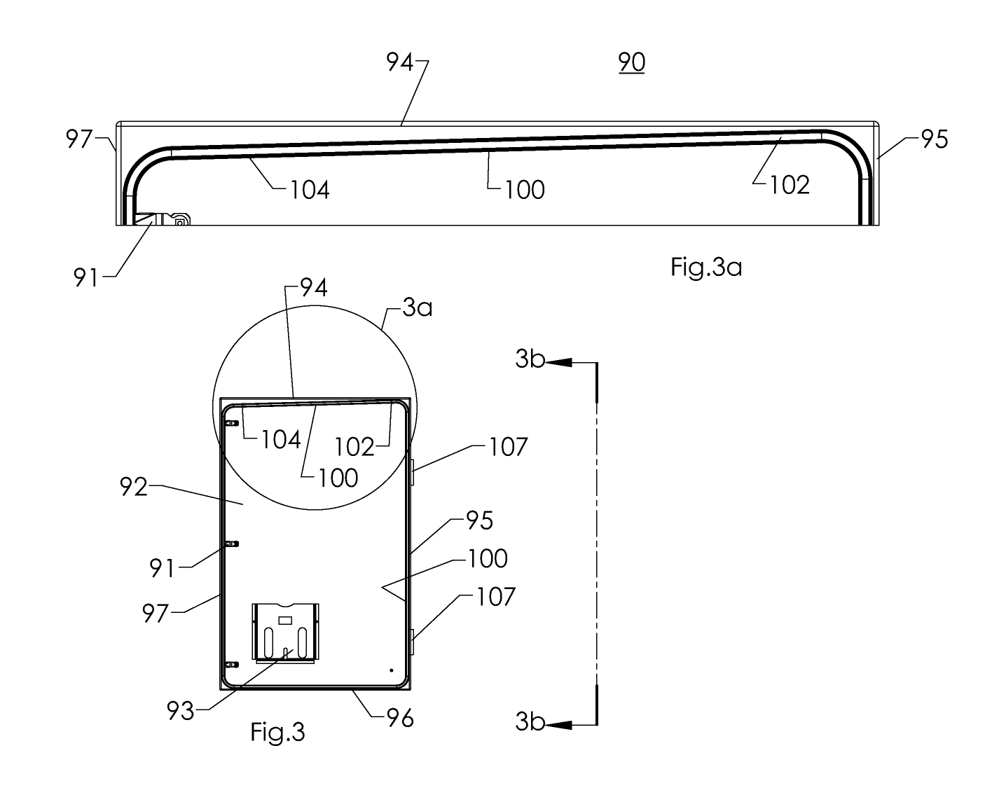

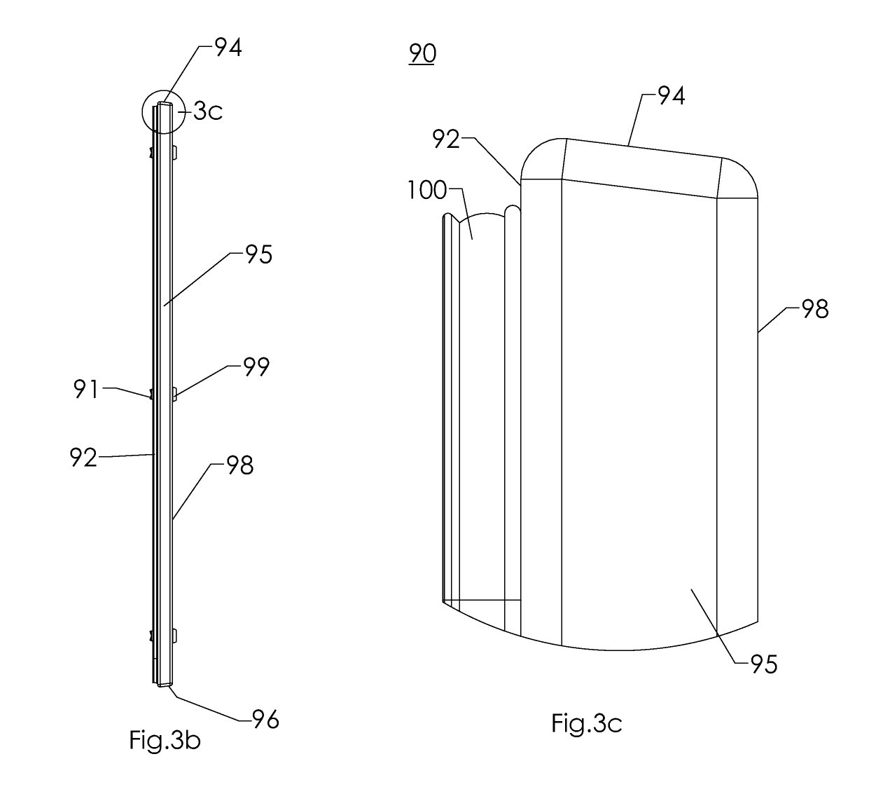

FIG. 3 illustrates an inner face 92 of a door 90 configured in accordance with a third embodiment of the present invention. The door 90, like door 14, is configured to seal an access opening of an enclosure in the closed position. The door 90 has an outer or front face and an inner or rear face 92. Rotating levers or arms 91 on the inner face 92 of the door 90 function to lock the door 90 when the door 90 is in a closed position. The levers 91 rotate to a position behind a front of an enclosure to lock the door 90 in the closed position sealing an opening on a front of an enclosure. A compartment 93 is located on the inner, back, or rear face 92 of the door 90 for holding paper instructions. The door 90 includes a top 94, a bottom 96, and sides 95 and 97. A gasket 100 is shown adjacent to the periphery of the door 90, except for being curved in the corners and angled downward at the top 94 of the door 90.

In accordance with the present invention, a gasket 100 is connected to inner face 92 of the door 90 and located at least over a top of an access opening of an enclosure when the door 90 is in the closed position on the enclosure. The gasket 100 is located closer to a top 94 of the door 80 in a first location 102, and the gasket is further from the top 94 of the door 90 in a second location 104 than the first location 102. As a variation from the embodiment shown in FIG. 1, the gasket 100 is angled downwards towards the side 97 of the door 90.

By angling the top of the gasket 100 in a downward manner, water contacting the top of the gasket 100 will not pool or remain on the gasket 100, but will run off the gasket 100 to the side 97 of the door 90 due to the force of gravity. By preventing water from accumulating or pooling on the gasket 100, the chance of water penetrating a seal between the inner face 92 of the door 90 and a front of an enclosure are greatly reduced.

FIG. 3a is an enlarged view of the portion “3a” shown in FIG. 3 showing the top 94 of the door 90. The gasket 100 is shown being angled downward towards the side 97 and away from hinges 107 on the door 90. The first location 102 and the second location 104 of the gasket 100 proximate to the top 94 of the door 90 are illustrated.

FIG. 3b is a view of the side 95 of the door 90 shown in and taken along line 3b-3b of FIG. 3a. Shown are the rotating levers 91 of the inner face 92 of the door 90, and the knobs 99 on the outer face 98 of the door 90 for rotating and locking the rotating levers 91. The top 94 and the bottom 96 of the door 90 also are illustrated.

FIG. 3c is an enlarged view of the circled portion “3c” shown in FIG. 3b. FIG. 3c is an enlarged view showing the gasket 100 connected to the inner face 92 of the door 90. The top 94 of the door 90 is angled downward toward the outer face 98 of the door 90 to drain water away from the gasket 100.

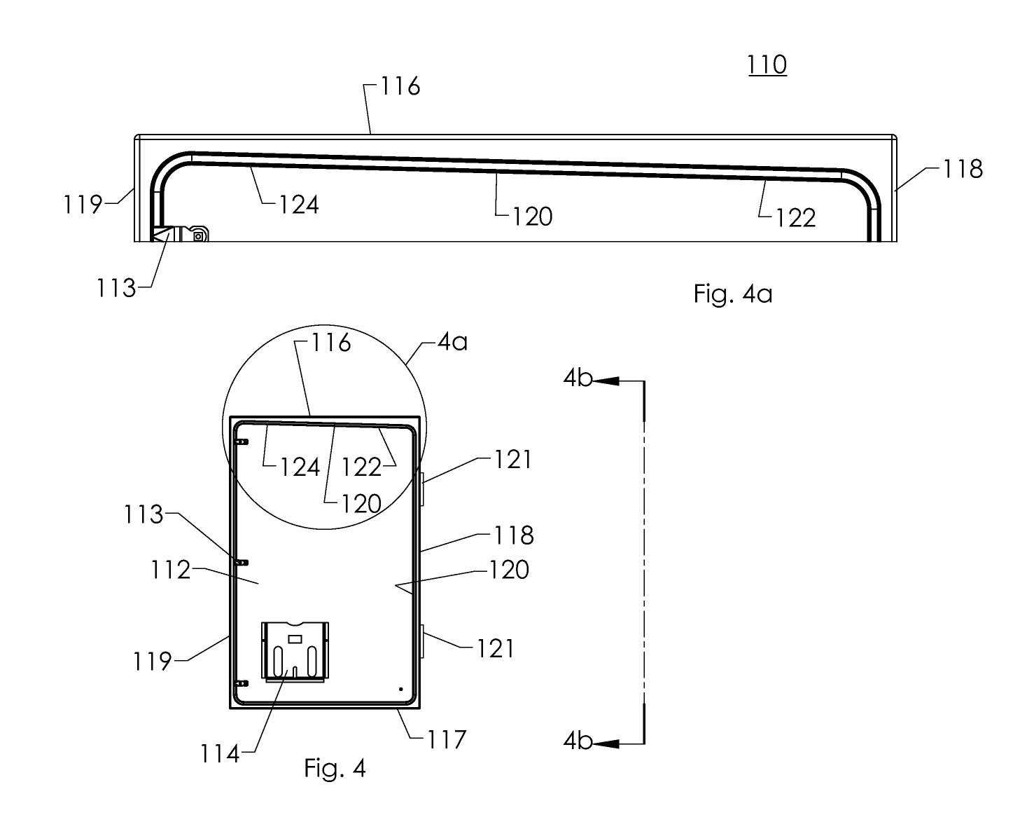

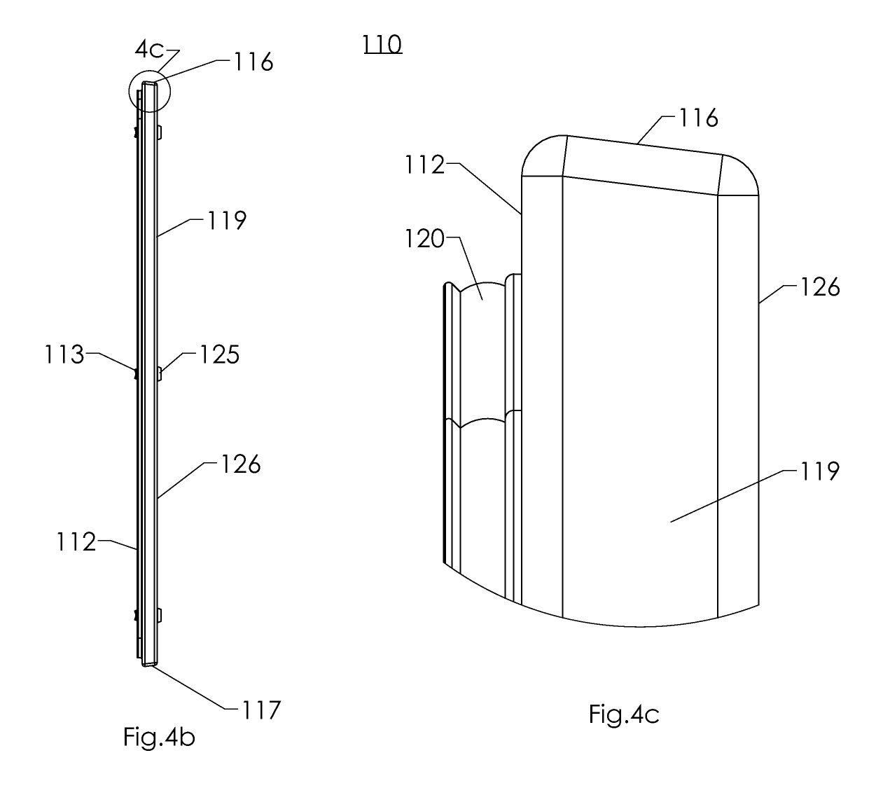

FIG. 4 illustrates an inner face 112 of a door 110 configured in accordance with a fourth embodiment of the present invention. The door 110, like door 14, is configured to seal an access opening of an enclosure when the door 110 is in the closed position over the access opening. The door 110 has an outer or front face and an inner or rear face 112. Rotating levers or arms 113 on the inner face 112 of the door 110 function to lock the door 110 when the door 110 is in a closed position. The levers 113 rotate to a position behind a front of an enclosure to lock the door 110 in the closed position sealing an opening on a front of an enclosure. A compartment 114 is located on the inner, back, or rear face 112 of the door 110 for holding paper instructions. The door 110 includes a top 116, a bottom 117, and sides 118 and 119. A gasket 120 is shown adjacent to the periphery of the door 110, except for being curved in the corners and angled downward towards a side 118 and hinges 121 on the door 110.

In accordance with the present invention, a gasket 120 is connected to inner face 112 of the door 110 and located at least over a top of an access opening of an enclosure when the door 110 is in the closed position over the access opening. The gasket 120 is located closer to a top 116 of the door 110 in a first location 124, and the gasket is further from the top 116 of the door 110 in a second location 122 than the first location 124. As a variation from the embodiment shown in FIG. 1, the gasket 120 is angled downward towards the side 118 and the hinges 121 of the door 120.

By angling the top of the gasket 120 in a downward manner, water contacting the top of the gasket 100 will not pool or remain on the gasket 100, but will run off the gasket 100 to the side 97 of the door 90 due to the force of gravity. By preventing water from accumulating or pooling on the gasket 120, the chance of water penetrating a seal between the inner face 112 of the door 110 and a front of an enclosure are greatly reduced.

FIG. 4a is an enlarged view of the portion shown in FIG. 4 showing the top 116 of the door 110. The gasket 120 is shown being angled downward towards the side 118 of the door 110. The first location 124 and the second location 124 of the gasket 120 proximate to the top 116 of the door 110 are illustrated.

FIG. 4b is a view of the side 119 of the door 110 shown in and taken along line 4b-4b of FIG. 4a. Shown are the rotating levers 113 of the inner face 112 of the door 110, and the knobs 125 on the outer face 126 of the door 110 for rotating and locking the rotating levers 113. The top 116 and the bottom 117 of the door 110 also are illustrated.

FIG. 4c is an enlarged view of the circled portion “4c” shown in FIG. 4b. FIG. 4c is an enlarged view showing the gasket 120 connected to the inner face 112 of the door 110. The top 116 of the door 110 is angled downward towards the outer face 126 of the door 110 to drain water away from the gasket 120.

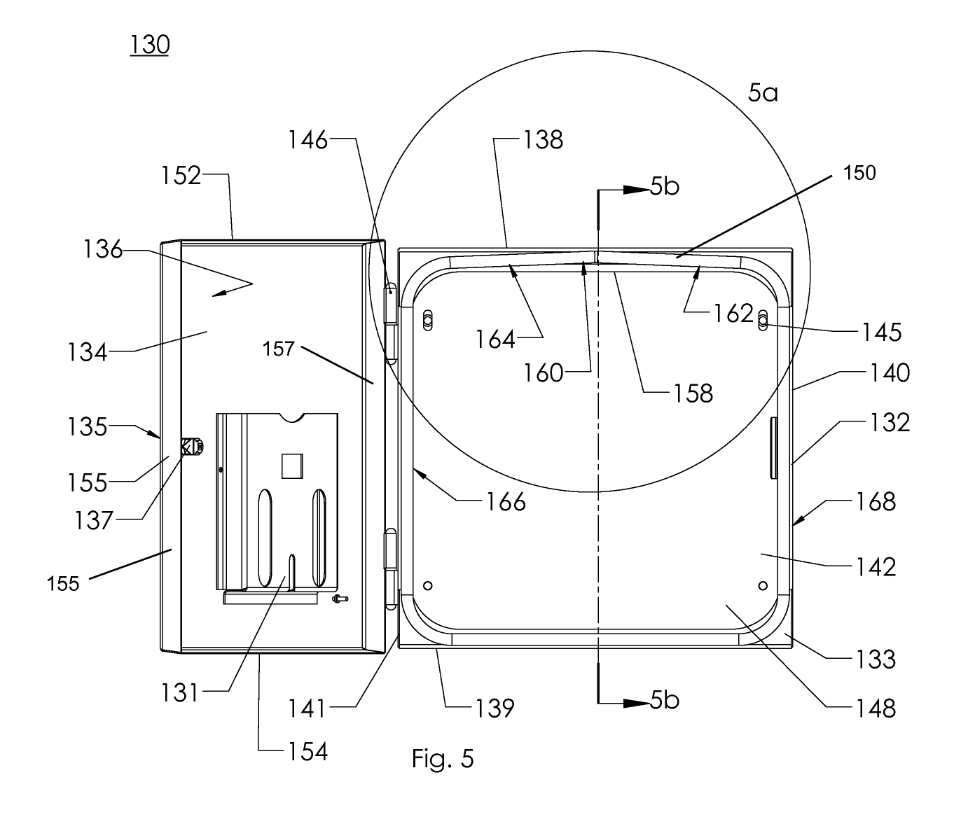

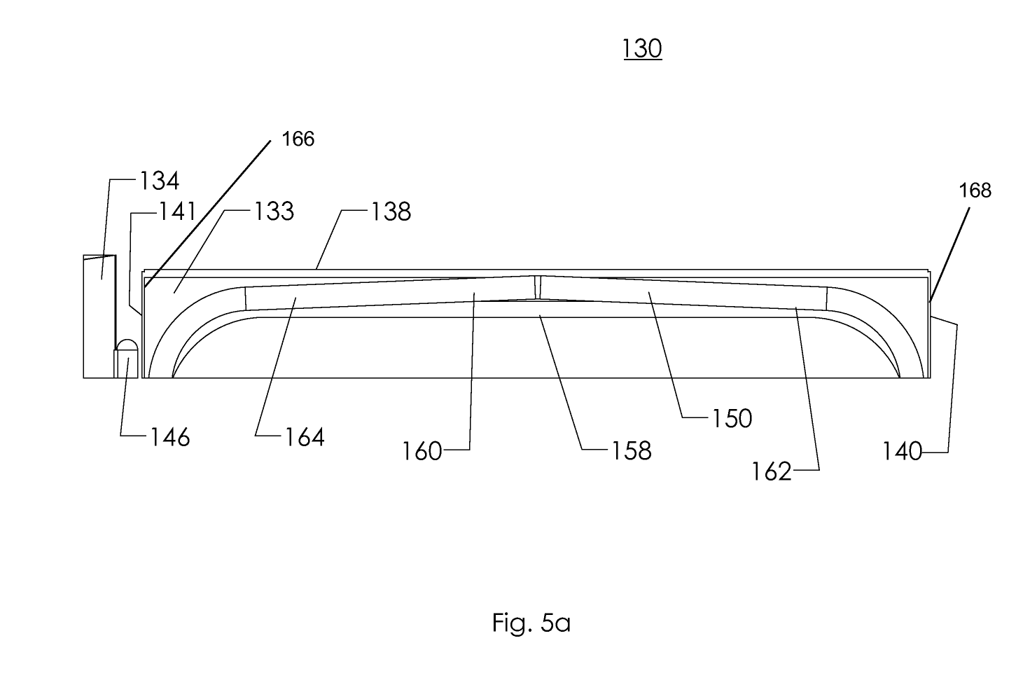

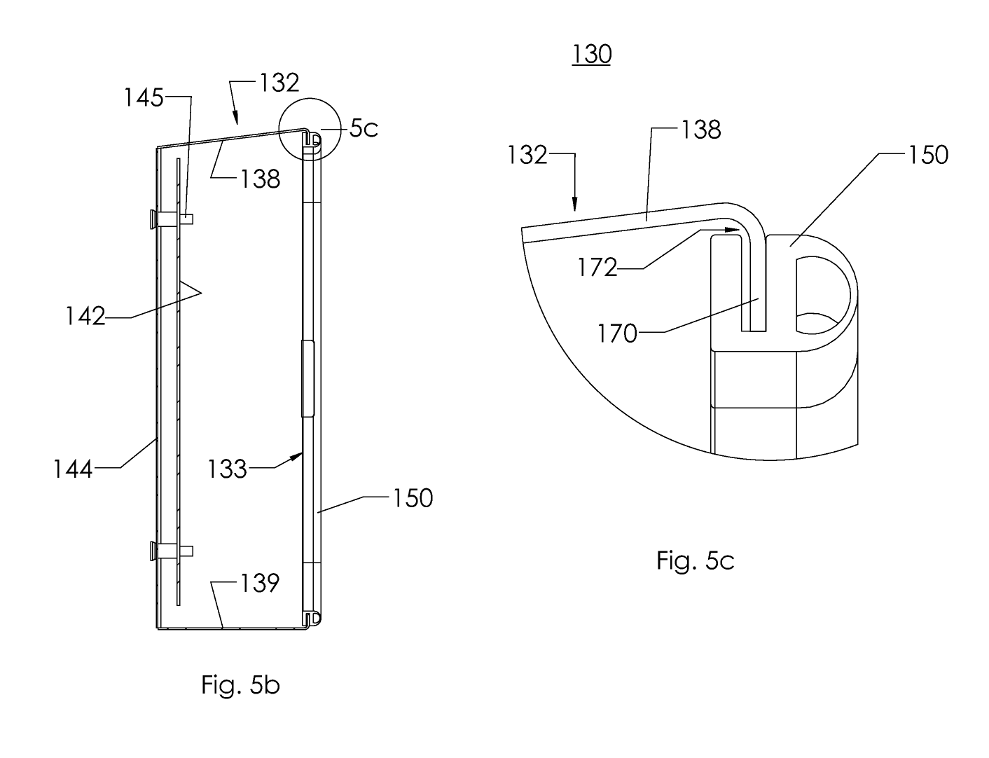

FIG. 5 is a perspective view of an enclosure 130, such as a watertight enclosure, configured in accordance with a fifth embodiment of the present invention. The enclosure 130 includes a housing 132 having a door 134 rotatably mounted to a front 133 of the housing 132. The housing 132 has a top wall 138, a bottom wall 139, and side walls 140 and 141. A back panel 142 for mounting electronics is secured or mounted to a back wall 144 (FIG. 5b) of the enclosure 130 using mounting fasteners 145.

The door 134 is rotatably mounted to the front 133 of the housing 132 using a hinge 146 or other rotatable mounting device. The door 134 has an outer or front face 135 and an inner or rear face 136. Rotating levers or arms 137 on the inner face 136 of the door 134 function to lock the door 134 when the door 134 is in a closed the position. The lever 137 rotates to a position behind the front 133 to lock the door 134 in the closed position. A compartment 131 is located on the inner face 136 of the door 134 for holding paper instructions. An access opening 148 is located on the front 133 of the housing 132. The access door 134 covers the opening 148 when the door 134 is in the closed position. The door 134 includes a top 152, a bottom 154, and sides 155 and 157.

In accordance with the present invention, a gasket 150 is connected to a front 133 of a housing 132 and located at least over a top 158 of an access opening 148 of the housing 132. The gasket 150 forms a watertight seal between the front 133 of the housing 132 and the inner face 136 of the door 134. The gasket 150 is located closer to a top 138 of the housing 132 in a first location 160, and the gasket 150 is located further from the top 138 of the housing 132 in a second location 162 than the first location 160. The gasket 150 also is further from the top 138 of the housing 132 in a third location 164. By angling the gasket 150 in a downward manner from a top 138 of the housing 132, water contacting on the top of gasket 150 will not pool or remain on the gasket 150, but will run off the gasket 150 to the sides 166 and 168 of the housing 132 due to the force of gravity. By preventing water from accumulating or pooling on the gasket 150, the chance of water penetrating a seal between the inner face 136 of the door 134 and the front 133 of the housing 132 are greatly reduced. Furthermore, water is less likely to enter the access opening 148 of the enclosure 132 when the door 134 covering the access opening 148 is opened.

FIG. 5a is an enlarged view of the portion “5a” shown in FIG. 5 showing the top 138 of the housing 132. The gasket 150 is shown being angled downward toward the sides 166 and 168 of the housing 132. The first location 160, the second location 162, and the third location 164 of the gasket 150 on the front 133 of the housing 132 are illustrated.

FIG. 5b is a cross-sectional side view of the housing 132 shown in FIG. 5. Illustrated are the top 138 and bottom 139 of the housing 132. The rear wall 144 and the rear panel 142 are further illustrated. The gasket 150 is shown on the front 133 of the housing 132.

FIG. 5c is an enlarged cross-sectional view of the circled portion “5c” shown in FIG. 5b. Illustrated are the top 138 of the housing 130 and the gasket 150. The gasket 150 includes a slot 172 for receiving a rim 170 of the opening 148 on the front 133 of the housing 132. The slot 172 enables the gasket 150 to slide over the rim 170 to be secured to the rim 170. The gasket 150 can be easily replaced if damaged or worn by sliding the gasket 150 off the rim 170, and replaced with a new gasket 150 that is slid back onto the rim 170.

While specific embodiments have been shown and described to point out fundamental and novel features of the invention as applied to the preferred embodiments, it will be understood that various omissions and substitutions and changes of the form and details of the invention illustrated and in the operation may be done by those skilled in the art, without departing from the spirit of the invention.

1. An enclosure, comprising:
a housing having a front wall and a back wall, and an opening in the front wall;
a door having a top and a bottom and an inner face and an outer face, the door being rotatably attached to the housing, and the door being configured to cover the opening when the door is in a closed position;
a gasket attached to the inner face of the door and located at least over a top of the opening of the housing when the door is in the closed position; and
the gasket being located closer to a top of the door in a first location, and the gasket being further from the top of the door in a second location than the first location.

2. The enclosure of claim 1, wherein the first location is approximately in the center of the door, and the second location is proximate a first side of the door.

3. The enclosure of claim 1, wherein a third location is proximate a second side of the door, and the gasket is located further from top of the door in the third location than the first location.

4. The enclosure of claim 1, wherein the first location is proximate a first side of the door, and the second location is proximate a second side of the door.

5. The enclosure of claim 1, wherein the gasket includes a slot, and the door includes a rim on the inner face of the door that surrounds an outer periphery of the top of the opening when the door is in the closed position, and the gasket is attached to the rim by sliding the rim into the slot of the gasket.

6. The enclosure of claim 1, wherein the door is rotatably connected to the housing by a hinge.

7. The enclosure of claim 1, further comprising:
rotatable lever arms on the inner face of the door for securing the door closed in the closed position.

8. The enclosure of claim 1, further comprising:
a bracket on the rear wall of the housing for securing the housing to a vertical wall.

9. The enclosure of claim 1, further comprising:
a rear panel for mounting electronic components that is secured to the back wall using bolts.

10. The enclosure of claim 1, wherein the gasket surrounds the outer periphery of the opening when the door is in the closed position.

11. An enclosure, comprising:
a housing having a front wall and a back wall, and an opening in the front wall;
a door having a top and a bottom and an inner face and an outer face, the door being rotatably attached to the housing, and the door being configured to cover the opening when the door is in a closed position;
a gasket attached to the front of the housing and located at least over a top of the opening of the housing;
the gasket being located closer to a top of the housing in a first location, and the gasket being further from the top of the housing in a second location than the first location.

12. The enclosure of claim 11, wherein the first location is approximately in the center of the housing, and the second location is proximate a first side of the housing.

13. The enclosure of claim 11, wherein a third location is proximate a second side of the housing, and the gasket is located further from top of the housing in the third location than the first location.

14. The enclosure of claim 11, wherein the first location is proximate location a first side of the housing, and the second location is proximate a second side of the housing.

15. The enclosure of claim 11, wherein the gasket includes a slot, and the opening includes a rim that surrounds an outer periphery of the top of the opening, and the gasket is attached to the rim by sliding the rim into the slot of the gasket.

16. The enclosure of claim 11, wherein the door is rotatably connected to the housing by a hinge.

17. The enclosure of claim 11, further comprising:
rotatable lever arms on the inner face of the door for securing the door closed in the closed position.

18. The enclosure of claim 11, further comprising:
a bracket on the rear wall of the housing for securing the housing to a vertical wall.

19. The enclosure of claim 11, further comprising:
a rear panel for mounting electronic components that is secured to the back wall using bolts.

20. The enclosure of claim 11, wherein the gasket surrounds the outer periphery of the opening.
